(19) United States
(12) Patent Application Publication
(10) Pub. No.: US 2025/0178219 A1
(43) Pub. Date: Jun. 5, 2025

(54) ESD PREVENTION BY RESISTIVE COATINGS OF ROBOT END EFFECTOR FINGERS AND CONDUCTIVE PAD

(71) Applicant: Applied Materials, Inc., Santa Clara, CA (US)

(72) Inventors: Srikanth V. RACHERLA, Fremont, CA (US); Makoto INAGAWA, Palo Alto, CA (US); Tsunehiko KITAMURA, Santa Clara, CA (US)

(21) Appl. No.: 18/965,237

(22) Filed: Dec. 2, 2024

Related U.S. Application Data
(60) Provisional application No. 63/604,850, filed on Nov. 30, 2023.

(51) Int. Cl. B25J 19/00; B05D 5/12; B25J 15/00

(52) U.S. Cl. CPC B25J 19/0075; B05D 5/12; B25J 15/0014

(57) ABSTRACT

An end effector for a substrate supporting and transferring system includes a wrist, a plurality of electrically insulative substrate support members extending from the wrist and having a proximal portion supported therein, the substrate supporting member including a substrate facing surface, a conductive coating, and at least a first conductive member disposed upon and in electrical contact with the conductive coating, the conductive coating extending from the conductive member to the proximal end of the support member; and a connection member extending between the conductive coating and the wrist. In one aspect, the conductive member includes a conformable or compliant conductive element, coupled to a conductive plate.

### CROSS-REFERENCE TO RELATED APPLICATIONS

This application claims benefit of U.S. provisional patent application Ser. No. 63/604,850, filed Nov. 30, 2023, which is herein incorporated by reference.

### BACKGROUND

### Field

Embodiments of the present disclosure generally relate to apparatuses, systems and methods for processing one or more substrates, and more specifically to apparatuses, systems, and methods for the dissipation of charge to suppress the occurrence of electrostatic discharge between a movable support structure and a substrate supported thereon.

### Description of the Related Art

Flat panel processing is typically performed by subjecting a large area substrate to a plurality of sequential processes to create devices, conductors, and insulators on the substrate. Each of these processes is generally performed in a process chamber configured to perform one or more steps of the production process. In order to efficiently perform one or more processing operations, a number of process chambers and a load lock chamber are coupled to a central transfer chamber that houses a robot. The transfer chamber and robot facilitate transfer of the substrate between the load lock chamber and the process chambers, or between the process chambers. Processing platforms having this configuration are generally known as cluster tools. Cluster tools include a robot therein to transfer the substrate, such as a flat panel substrate, between the different chambers in the cluster tool. Such robots are also used to load the substrates into one or more load lock chambers connected to the cluster tool from the side of the load lock chamber opposite to the central transfer chamber. In one such robot, an end effector configured to support the substrate includes a plurality of rods, commonly called fingers, extending generally parallel to one another from a base plate, commonly called a wrist. The wrist is connected to a motion mechanism, which includes a mechanism such as a linear slide to move the wrist horizontally, and a rotary drive system configured to rotate the linear drive mechanism and thus move the wrist in a rotational or orbital path about the center of rotation of the rotary drive system.

To minimize the generation of particulates from contact between the supporting rods and the substrate supported thereon, the rods of the end effector include pads thereon. The pads are approximately the same width as the width of the rods and significantly smaller in a length direction than the span of the rods. The pads are located on the upper surface of the rods. Thus, a substrate, such as a sheet of glass used in the manufacture of a flat panel display, rests upon the pads as the wrist is moved to move the substrate between the various process chambers. The pads minimize the contact area between the rods and the substrate, and the interface of the top surface thereof with the underside of the substrate provides sufficient friction to maintain the substrate in position on the pads.

Large area substrates are often utilized in the manufacture of liquid crystal displays (LCDs) and other types of displays. These large area substrates are commonly dielectric materials, such as glass. Displays, or flat panels, include liquid crystal or organic light emitting diode (OLED) light emitting elements formed over control circuitry on the large area substrate for active matrix displays, such as those used for computers, touch panel devices, personal digital assistants (PDAs), cell phones, television monitors, and the like. Processing to form the light emitting devices and the circuitry required to create a flat panel display may result in a yield issue caused by electrostatic discharge (ESD) between the large area substrate and the end effector pads on the rods, or between conductive elements (wirings) formed over the glass, particularly when the substrate is received on, or removed from, the end effector pads. This can result in localized destruction of one or more devices, such as transistors or portions thereof, or adjacent wirings, that were previously formed on the substrate, which are used to activate and deactivate individual light emitting elements in the panel. New approaches are needed to prevent the occurrence of this electrostatic discharge phenomenon.

### SUMMARY

In light of the above, embodiments of end effectors for a substrate supporting and transferring system, and a method of supporting a substrate to reduce the occurrence of electrostatic discharge within the substrate or one or more layers of material formed thereon are provided. Further aspects, embodiments, features and details can be derived from the dependent claims, the drawings and the specification.

According to one aspect, an end effector for a substrate supporting and transferring system is provided. The end effector includes a wrist, a plurality of electrically insulative substrate support members extending from the wrist and having a proximal portion supported therein, the substrate supporting member including a substrate facing surface, a conductive coating, and at least a first conductive member disposed upon and in electrical contact with the conductive coating, the conductive coating extending from the conductive member to the proximal end of the support member, and a connection member extending between the conductive coating and the wrist.

According to another aspect, a method of supporting a substrate to reduce the occurrence of electrostatic discharge within the substrate or one or more layers of material formed thereon is provided. The method includes providing an insulative substrate support member extending from a base plate, the substrate support member having a substrate facing surface and at least one protrusion extending therefrom and including a support surface configured to contact a substrate, and providing a conductive path from the support surface to the base plate.

According to another aspect, an end effector for a substrate supporting and transferring system is provided. The end effector includes a wrist, a plurality of substrate support members extending from the wrist and having a proximal portion supported therein, the substrate supporting member including a substrate facing surface, a conductive coating, and at least a first conductive member disposed upon and in electrical contact with the conductive coating, the conductive coating extending from the conductive member to the proximal end of the support member, and an electrically conductive connection member extending between the conductive coating and the wrist.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 depicts a simplified schematic diagram of a cluster tool, according embodiments herein.

FIG. 2 depicts an isometric view of one embodiment of an end effector and wrist assembly of a transfer robot suitable for use in a transfer chamber of a cluster tool of FIG. 1.

FIG. 3 depicts an isometric view of a simplified version of the one embodiment of an end effector and wrist assembly of a transfer robot suitable for use in a transfer chamber of a cluster tool of FIG. 1 including a conductive coating and pad for dissipating static charge.

FIG. 4 depicts a cross section of one embodiment of a conductive pad mounted on an end effector rod.

FIG. 5 depicts a side view of one embodiment of a conductive pad mounted on an end effector rod.

FIG. 6 depicts a plan view of one embodiment of a conductive pad on an end effector rod.

FIG. 7 depicts a partial isometric view of a robot wrist and an end effector rod connected thereto according to one embodiment hereof.

FIG. 8 depicts a clamp assembly for use in a connection between an end effector and wrist assembly of FIG. 7.

FIG. 9 depicts a cross sectional view of a portion of the wrist of FIG. 7 cut through the rod supporting portion of the rod receiving recess of the wrist.

FIG. 10 depicts a cross sectional view of a portion of the rod receiving portion of the wrist of FIG. 7 cut through the shim stack receiving portion of the rod receiving portion of the wrist.

FIG. 11 depicts a shim stack of the end effector and wrist assembly of FIG. 7.

FIG. 12 depicts a cross sectional view of one embodiment of a connection between an end effector and wrist assembly of FIG. 7.

FIG. 13 depicts a cross sectional view of the upper layers of the shim stack and rod in the wrist body of FIG. 12.

FIG. 14 depicts a cross sectional view of the lower layers of the shim stack and rod in the clamp of FIG. 12.

FIG. 15 depicts a cross sectional view of one embodiment of the conductive connection between the wrist assembly and the rod of FIG. 12.

FIG. 16 depicts a cross sectional view of one embodiment of the conductive connection between the wrist assembly and the rod of FIG. 12.

FIG. 17 depicts a cross sectional view of one embodiment of the conductive connection between the wrist assembly and the rod of FIG. 12.

FIG. 18 depicts an exploded view of one embodiment of the rod of FIG. 2.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

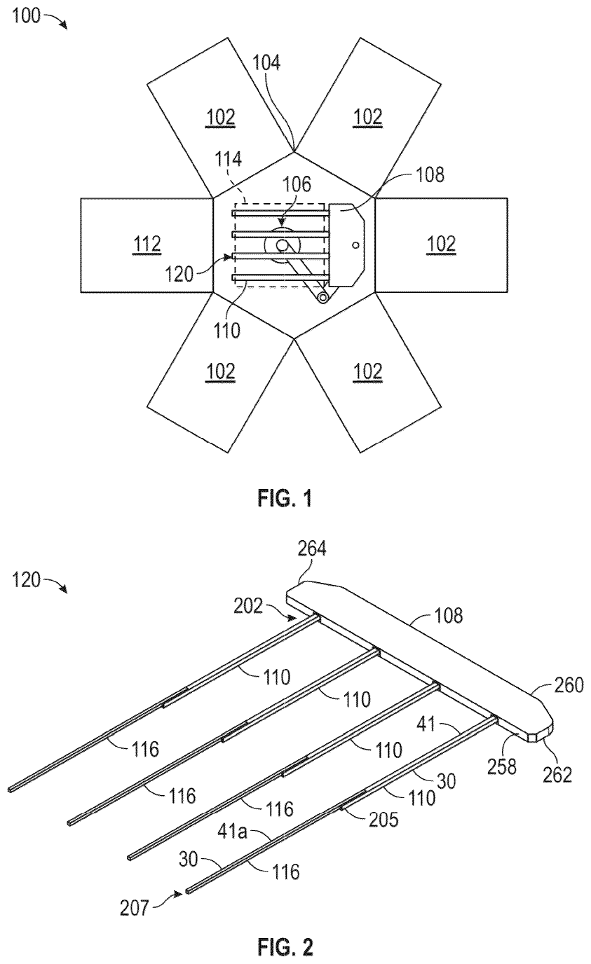

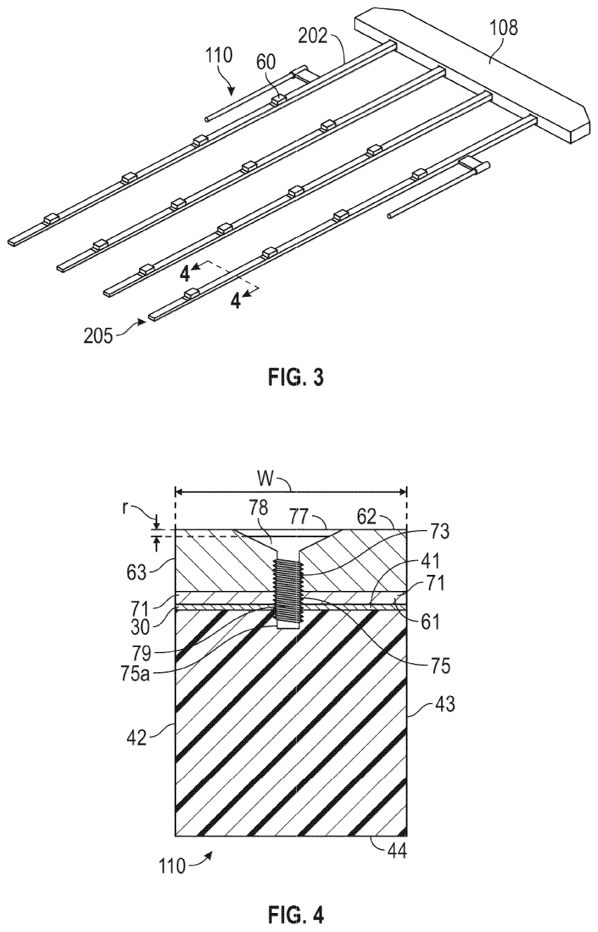

Herein, as shown in FIGS. 1 and 2, a robot end effector assembly 120 is provided. The robot end effector assembly 120 is configured to releasably support a substrate 114 thereon while allowing charge (positive or negative) to dissipate or to flow there along and thereby prevent or minimize electrostatic discharge between a substrate 114 and the end effector assembly 120 or between elements, such as conductive elements, previously formed on or over the substrate. Here, the end effector includes a wrist 108 and a plurality of substrate supporting rods 110 extending from a side face thereof. In some aspects hereof, an extension rod 116 (FIG. 2) extends from the distal end 205 of each rod 110 distal to the connection of the rod 110 with the wrist 108. The extension rods 116 have a smaller cross section than the rods 110, and thus have less mass than that of the rods 110 per equal unit of length thereof. The extension rods 116 are used in conjunction with the rods 110 for supporting larger area substrates. At least two conductive pads 60 (FIG. 3) are located on each rod 110 or on each rod 110 and each extension rod 116 connected thereto, to support the substrate from the facing surface of the rod 110 or extension rod 116. A conductive coating 30 is applied to each rod 110 and extension rod 116, when used, to create an electrically conductive path from the substrate facing surface of each pad 60, through the body of the pad 60, through the conductive coating 30 and to the wrist 108 of the end effector assembly 120. The wrist 108 is connected to a robot 106 which moves the end effector assembly. The wrist 108 may be connected to electrical ground to complete a ground path for an electrical charge. The ground path being from between the underside of the glass contacting the pad and the substrate facing surface of the pad 60 on which the substrate rests, to electrical ground.

The cluster tool 100 generally includes a transfer chamber 104 centrally located among a plurality of process chambers 102 and at least one load lock chamber 112 extending thereabout. Process chambers 102 are generally configured to perform one or more operations of the production process for creating a device, for example a flat panel display. For example, process chamber 102 may be a CVD chamber, an etch chamber, or any other process chamber as is conventionally known in the art. The transfer chamber 104, the load lock chamber 112, and the process chambers 102 are configured to selectively operate under vacuum conditions. The transfer chamber 104 generally includes a transfer robot 106 adapted to transfer a substrate 114 (shown in phantom in FIG. 1) into and out of the load lock chamber 112 and into and out of at least one of the various process chambers 102. When substrate processing in the cluster tool is completed, the transfer robot moves the substrate back into the load lock chamber 112. Substrates to be processed in the cluster tool 100, and substrates that have been processed in the cluster tool, are loaded into, and unloaded from, the load lock chamber through a valve (not shown) on the opposite side of the load lock chamber 112 from the transfer chamber 104. A valve (not shown) having a door covering a slit providing access into and from the process chambers 102 and load lock chamber 112 is provided at the interface of the transfer chamber 102 with each process chamber 102 and the load lock chamber 112. The substrate transfer robot 106 generally has an end effector assembly 120 that includes a plurality of rods, (also known as fingers) 110 extending from a wrist 108. The rods 110 are adapted to support the substrate 114 thereon during transfer by the robot 106. The robot can be any type of robot capable of arcuately or rotationally moving the end effector assembly 120 between the individual valves of a process chamber 102 and the load lock chamber 112, and to linearly move the end effector assembly inwardly and outwardly of a process chamber 102 and the load lock chamber 112.

Although the transfer robot 106 having substrate supporting rods 110 is suitable for use with conventional substrates, the transfer robot described herein is particularly useful for large area substrates having a surface area up to and exceeding four square meters, for example a rectangular glass sheet substrate used in the manufacture of flat panel displays. Although the end effector assembly 120 is shown coupled to the transfer robot 106 disposed in the transfer chamber 104, the transfer robot 106 may also be disposed exteriorly of the cluster tool 100, such as to load and unload substrates into and from the load lock chamber 112, or to load and unload substrates into an atmospheric pressure processing system, such as an electron beam test (EBT) chamber. One exemplary EBT chamber is described in U.S. Pat. No. 6,833,717, which issued Dec. 21, 2004, entitled “Electron Beam Test System with Integrated Substrate Transfer Module.” In addition, the end effector may be utilized in other robotic applications, including those in other vacuum and non-vacuum environments where efficient transfer of large area substrates is desired.

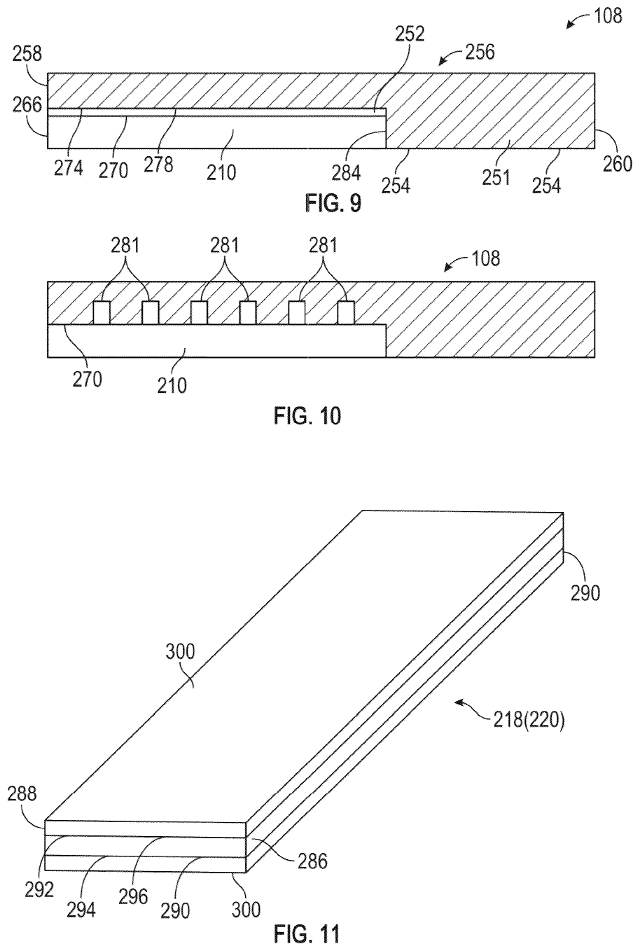

FIG. 2 depicts one embodiment of an end effector assembly 120. For clarity, the conductive pads 60 are not shown on the end effector assembly 120 in this figure. In the embodiment depicted in FIG. 2, the end effector assembly 120 includes a plurality of rods 110 and a wrist 108 to which the proximal end 202 of the rods 110 are secured in substantially parallel alignment with one another in the direction extending away from the front facing surface (third flat face 258 of FIG. 9) of the wrist 108. In FIG. 2, the end effector assembly 120 further includes extension rods 116, wherein an extension rod 116 extends from the distal end 205 of each rod 110 (at the end thereof distal to the connection thereof with the wrist 108). The extension rods 116 are smaller in cross section, and thus lighter per equal unit of length, than the rods 110, to reduce the mass (weight) of the end effector assembly 120. The rods 110 and extension rods 116 are configured and arranged such that a large area substrate may be supported or held by gravity by the rods 110 and extension rods 116 for movement thereof into and out of the load lock chamber 112 and process chambers 102 through the transfer chamber 106 of FIG. 1. The longitudinal axis of each of the plurality of rods 110 (and extension rods 116) are also aligned in the same plane generally extending from of the front face of the wrist 108 from which rods 110 project (in the direction perpendicular to gravity). As the mass of the large glass substrate (and of the rods 110 and extension rods 116 themselves) can cause the rods 110 and extension rods 116 to sag or droop over their length. That is, the span of the rods 110 extending from the wrist 108 (and optionally, the span of the extension rods 116 extending from the distal ends 205 of rods 110) extends downwardly under the influence of gravity. This includes the area from the proximal end 202 of the rods 110 connected to the wrist 108 to the distal end 205 of the rods 110, and to the distal free end 207 of the extension rod 116 distal to the connection of the extension rod 116 to the rod 110. To compensate for this droop, the rods 110 are affixed to the wrist 108 such that without supporting a substrate 114 thereon, the rods 110 are inclined upwardly from the wrist 108 to the free end 205 thereof, and the extension rods 116 connected thereto are similarly inclined from the connection of the extension rods 116 to the rods 110 at the distal end 205 of rods 110, to their distal ends 207. The slope of this incline is determined such that with the glass thereon, the rods 110 and extension rods 116 will extend horizontally or substantially horizontally (perpendicular or nearly perpendicular to the direction of gravity). Although four rods 110 are shown coupled to the wrist 108 in FIG. 2, it is contemplated that other quantities of rods 110 and extension rods 116 connected thereto, when used, e.g., at least two of each, may also be effectively utilized.

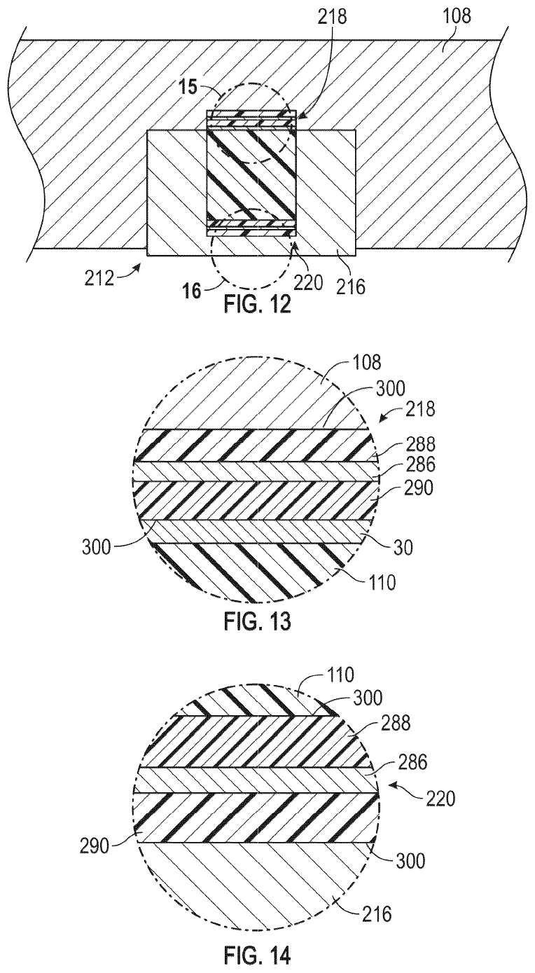

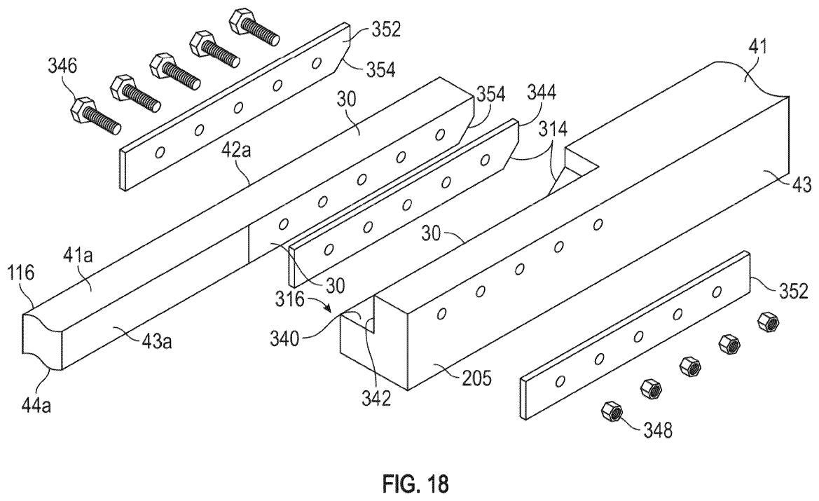

Here, each rod 110 and extension rod 116 is configured to have a generally trapezoidal structure in section. As shown in FIGS. 4 and 12, each rod 110 includes an outer upwardly facing first surface 41, an outer second surface 42, an outer third surface 43, and an outer fourth surface 44. Here the first surface 41 is orthogonal to the second surface 42 and to the third surface 43 and the third surface 43 and second surface 42 extend downwardly form the first surface 41, and the first surface is parallel to the fourth surface 44 which extends between the lower termini of the second surface 42 and third surface 43. Similarly, as shown in FIG. 18, each extension rod 116 includes a corresponding outer upwardly facing first surface 41a, an outer second surface 42a, an outer third surface 43a, and an outer fourth surface 44a. Here the first surface 41a is orthogonal to the second surface 42a and to the third surface 43a, and the third surface 43a and second surface 42a extend downwardly from the first surface 41a, and the first surface 41a is parallel to the fourth surface 44a, which extends between the lower termini of the second surface 42a and third surface 43a. In other words, the rods 110 and extension rods 116 are, in cross-section, rectangular.

The longitudinal axes of the rods 110 and of the extension rods 116 are aligned in the same horizontal plane to provide the end effector assembly 120 with a substantially level upper surface to support a substrate. The wrist 108 and other components of the transfer robot 106 are generally fabricated from materials selected to minimize thermal effects during substrate transfer. Examples of materials that are suitable for fabrication of the wrist 108 include, but are not limited to, aluminum/silicon carbide composites, ceramics (such as Neoceram N-0 and Neoceram N-11, among others), aluminum/iron composites, carbon, carbon matrix composites, cast aluminum alloy, commercially pure chromium, graphite, molybdenum, titanium alloy, molybdenum tungsten alloy, commercially pure molybdenum, Zerodur®, Invar®, titanium Ti-6Al-4V alloy, 8090 aluminum MMC, and metal matrix composites. Metal matrix composites generally include aluminum or other light metal such as magnesium, titanium, aluminum, magnesium alloys, titanium alloys and aluminum alloys with up to 30 percent fillers, such as silicon carbide and the like.

The rod 110 and the extension rod 116 of the end effector are generally fabricated from materials having high temperature durability. Density of the materials is also an important factor since the end effector may droop, or sag, due to its own weight. This effect may be exacerbated in high-temperature applications. Table 1, below, shows a non-exhaustive list of materials that can be used to fabricate the rod 110. The table provides the corresponding density in g/cm3 for each material and the Young's modulus in giga-Pascals (GPa). In addition, the final column of Table 1 shows the Young's modulus divided by the density—a relative parameter showing rigidity per density. The higher this calculated value is, the less droop or sag the rod 110 will incur. Conversely, the lower this value is, the greater the sag of the rod 110. Material selection for the fabrication of rod 110 may be made by selecting a material or combination of materials that minimize the droop of rod 110 or that provide an allowable amount of droop based upon the tolerances of the system design.

TABLE 1

| | | Young's | Young's |
|---|---|---|---|
| | Density | Modulus | Modulus/ |
| Material | (g/cm3) | (GPa) | Density |
| Ceramics (Alumina) | 3.8 | 370 | 97 |
| MMC (Metal Matrix Composite) | | | |
| Base Mat: Si, Reinforced Mat: SiC | 2.8 | 270 | 96 |
| Base Mat: Al, Reinforced Mat: Al2O3 | 3.4 | 210 | 62 |
| Al Be matrix (AlBeMet 162) | 2.1 | 193 | 92 |
| CFRP (Carbon Fiber) | 1.7 | 300 | 176 |
| Aluminum (6061) | 2.7 | 69 | 26 |
| SST (304 L) | 8 | 200 | 25 |

As can be seen from Table 1, carbon fiber reinforced polymer (CFRP) has the highest rigidity per density followed by alumina, metal matrix composite (MMC) having a silicon base reinforced with silicon carbide, then an aluminum beryllium matrix comprising approximately 38 percent Aluminum and approximately 62 percent Beryllium. One example of such an Al—Be alloy is AlBeMet® 162, available from Brush Wellman, Inc., located in Cleveland, Ohio. AlBeMet® is a registered trademark of Brush Wellman, Inc.

In one embodiment, the rod 110 and the extension rod 116 of the end effector 120 may be made of ceramic due to a low propensity to sag or droop and high temperature durability. Examples of suitable ceramics include, but are not limited to, alumina, silicon carbide, silicon nitride, and the like. The rod 110 (and extension rod 116) are generally designed so that each piece of the rod 110 (extension rod 116) is of a size that can be made within existing ceramic firing furnaces. It is contemplated that the rod portion of the end effector assembly 120 may alternatively be made in one piece if suitably sized furnaces are used, such that a longer rod 110 would be supplied to the full length required. To minimize the contact are between the span of the first surface 41 (and 41a, where extension rod 116 is used), support pads or other protrusions are spaced along the length of the first surface 41 (and 41a, where extension rod 116 is used). It has been found that localized charging on this protrusion can result in electrostatic discharge. Not by way of limitation, it is believed that during the processing or the large area substrates, a charge of one polarity (+ or −) can accumulate on the side of the substrate 114 facing away from the end effector assembly 120, and charge of the opposing polarity can accumulate on the end effector assembly 120, including the surface of the protrusion on which the underside of the substrate 114 is supported. As a result, an electrostatic discharge can occur through the substrate, resulting in destruction of a portion of a device, for example of an insulative layer in a semiconductor device on the glass. For example no conductive elastomeric pads have been used between the rods 110 (and rods 116 when used) and the underside of the substrate 114, to support the substrate 114 above the rods 110 (and rods 116 when used). As a result of the construct of the non-conductive pads and the rod 110 (and extension rod 116) being configured of a low-electrical conductivity or a non-electrically conductive material, charge can accumulate on the end effector assembly 120 leading to electrostatic discharge.

FIG. 3 shows an end effector assembly 120 hereof, including the rods 110, the wrist 108, and a plurality of conductive pads 60 mounted to the upwardly facing first surface 41 of the rods 110. Here, the end effector assembly 120 is simplified and does not include the extension rods of FIG. 2. Here, the rods 110 are configured of an electrically insulative material, for example an electrically insulative ceramic material, and the first surface 41 of each of the rods 110 is covered with the conductive coating 30. The conductive coating 30 is a material capable of conducting and thus dissipating static charge formed on the substrate 114 facing surface of the pads 60 or on the pad-facing side of the substrate 114 in contact with the pads 60. Here, the pads 60 are configured as conformable, and conductive, such that an electrically conductive path is formed through the pad 60. The conductive pad 60 is placed into electrical contact with the conductive coating 30, and thus charge on the conductive pad 60 will discharge (flow) through the conductive coating 30 on the rod 110 to the wrist 108. The robot 106 and wrist 108 may together provide sufficient capacitance to hold the accumulated charge dissipated from the pads 60 and the conductive coating 30 thereto, or the robot 106 may provide a ground connection inherently or additively (such as through a conductive brush between moving parts thereof), to electrical ground. Here, for example, the capacitance between opposed ends of the end effector are one the order of 109 ohms. Thus, the conductive coating 30 although conductive compared to the underlying end effector material, can be considered dissipative in that the conductive coating 30 can allow charge to flow thereinto and become trapped therein. The conductive coating 30 material is for example, a ceramic material such as a doped Al₂O₃, which is doped for increased electrical conductivity thereof. The conductive coating 30 may be applied to the first surface 41 of the rod and/or to the first surface 41 of the extension rod (through spraying, for example by plasma spray coating or other coating process, such as physical vapor deposition, chemical vapor deposition or other spray coating, or otherwise manually applied). The conductive coating 30 is applied to a thickness sufficient to enable charge to flow therethrough to the wrist 108, for example a thickness of 5 to 6 microns. The conductive coating 30 extends over at least the first surface 41 of the rods 110 from the proximal end 202 thereof connected to the wrist 108 to the distal end 205 thereof at a continuous thickness within manufacturing tolerances. The conductive coating 30 may cover only the first surface 41 of the rod 110 or it may extend over one or both of the second surface 42 and the third surface 43 forming the side walls of the rod 110 (or 42a, 43a forming the side surface of the extension rod 116).

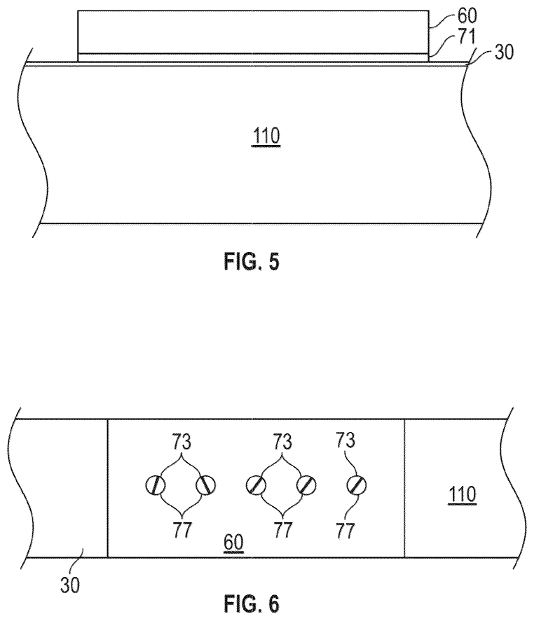

Referring to FIGS. 4-6, in one aspect the conductive pads 60 are constructed of a conductive conformable material, for example an elastomeric material such as a low outgassing vacuum compatible rubber material. The low outgassing vacuum compatible rubber material is compatible with the use in a vacuum environment, and is, for example, impregnated or formed with sufficient conductive fillers to render the low outgassing vacuum compatible rubber material conductive in the direction from the top to the underside of the pad 60. For example, a conductive Viton® material. The conductive pad 60 is here dimensioned to have a width w in the direction between the second and third surfaces 42, 43 of the rod 110 equal to the distance between the second and third surfaces 42, 43 (and the second and third surfaces 43a, 43b of the extension rod 116, where used). In other words, in a width direction, the pad 60 has the same width was the distance between the second and third surfaces 42, 43. The pad 60 includes a first pad surface 61 and a second pad surface 62, surrounded by a pad perimeter wall 63, with the second pad surface 62 located on the pad 60 opposite to the location of the first surface 61. The conductive pad 60 is mechanically fastened to the rod 110 (or extension rod 116) by, for example, screwing, bolting, welding, bonding, gluing, the pad 60 thereto, and the like. In one example, a conductive base plate 71 is provided, to which the pad 60 is adhered, such as by being molded thereto in an insert molding process or adhered thereto with a conductive adhesive, such that the first pad surface 61 of the pad 60 is in electrically conductive contact with the base plate 71. One or more countersunk openings 73 extend through the pad 60 from the second pad surface 62 side to the first pad surface 62 side thereof, and are aligned with a through opening 75 extending through the base plate 71. One or more threaded openings 75a extend inwardly of the first surface 41 of the rod 110 and through the conductive coating 30 thereon, and the one or more through openings 75 in the base plate 71 are aligned with the one or more threaded openings 75a in the rod 110. Here, the threaded fasteners 77 can be bolts having heads with a frustoconical head sidewall 78 and a threaded shank 79 extending therefrom, extending the shank 79 of the fastener 77 through the countersunk opening 73 and through openings 75 in the base plate 71, and threaded in the end of the threaded shank 79 into the threaded opening 75a, and tightening the fastener 77 into the threaded opening 75a pulls the underside of the base plate 71 facing away from the pad 60 against the conductive coating 30 to ensure electrical continuity between the substrate contacting first surface 61 of the pad 60 and the conductive coating 30 on the rod 110. Here, the heads of the threaded fasteners 77 are recessed below the second pad surface by a small distance r, to ensure that the threaded fasteners 77 do not come into contact with the substrate when on the end effector assembly 120. The threaded fasteners can be conductive, for example configured of a metal, or non-conductive, for example configured of a ceramic or a high temperature resistance plastic

Each conductive pad is 60 sized, and fastened or connected to the rod 110, so that the second surfaces 62 of the pads 60 are at the same or substantially the same elevation above the first surface 41 of the rod 110. A plurality of conductive pads 60 are located on the first surface 41 of each rod 110, and are spaced from one another and from the distal end 205 and proximal end 202 or the rod 110. As the substrate 114 is relatively stiff, but large in area and thin, the substrate 114 will sag or droop between locations where it is supported by the pads 60. The conductive pads 60 are spaced from one another along the length of each rod 110 in the direction between the proximal end 202 and distal end 205 thereof to provide sufficient support of the substrate off of the conductive coating 30 such that the substrate 114 will not contact the portion of the conductive coating 30 between the pads 60. Likewise, the distance between the pad 60 closest to the proximal end 202 of the rod 110 is spaced from the proximal end 202 of the rod 110. The spacing is such that any portion of a substrate 114 extending between the pad 60 closest to the proximal end 202 of the rod 110 and to the wrist 108 will not contact the conductive coating at a location between that pad 60 and the wrist 108. The pad 60 closest to the distal end 205 of the rod 110 is spaced from the distal end 205 of the rod 110. It is spaced such that any portion of the substrate extending between that pad 60 and the distal end 205 of the rod 110 will not contact the conductive coating 30 at a location between that pad 60 and the distal end of the rod 110. The width of each conductive pad 60 may span the width of the first surface 41 of each end effector between the second surface 42 and the third surface 43, of the rod 110, or the conductive pad 60 may be smaller in width than the width of the first surface 41 of each rod 110 extending between the second surface 42 and the third surface 43. Each conductive pad 60 is aligned along the length of the rod the same spacing from each of the second surface 42 and the third surface 43 on the first surface 41.

Alternatively, the conductive pad 60 can be releasably connected to the rod. Here, to connect the pad to the end effector, a metal plate having a tab is connected to the end effector. A base, having a spring loaded wedge with a wedge profile, is connected to the end effector over the metal plate. A pad, having a mating conductive wedge profile extending from the underside thereof, is loaded against the mating profile, and the spring loaded wedge profile biases against the conductive wedge profile on the pad to secure the pad against the base and to pull the conductive wedge profile against the tab on the metal plate.

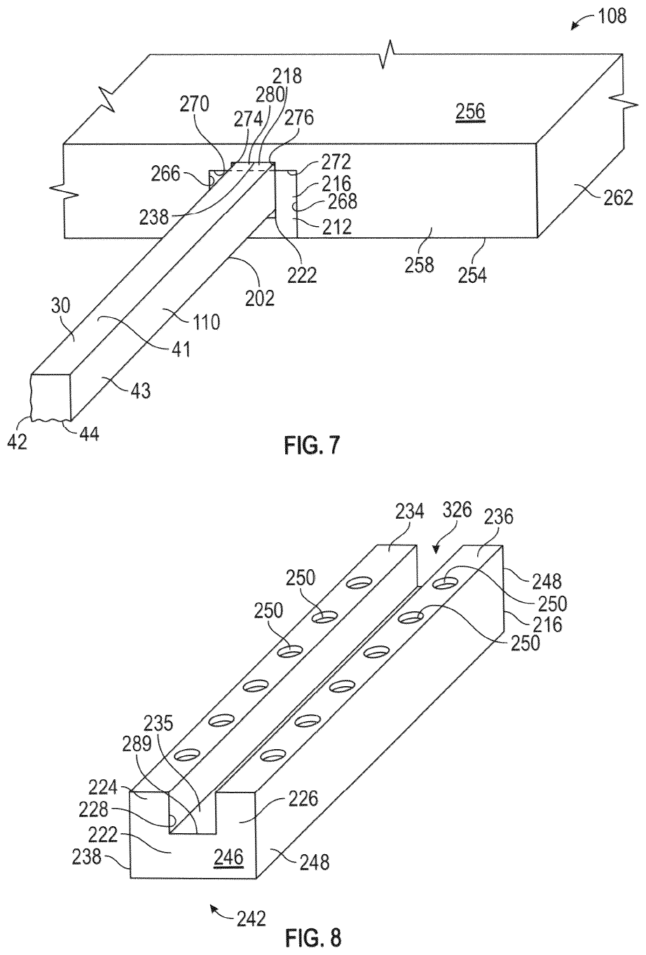

Referring now to FIGS. 7 to 14, the connection of a rod 110 to the wrist 108 is illustrated. In this aspect, the rods 110 are connected to a recess the lower side of the wrist 106. The same paradigm as described herein can be used to connect the rod 110 to a recess in the upper surface of the wrist. Here, the proximal end 202 of each rod 110 is extended inwardly of a three-sided recess 210 extending inwardly of the wrist 108, and clamped thereinto using a clamp assembly 212. Here, as best shown in FIGS. 9 and 10, the clamp assembly 212 includes a clamp body 216 and a plurality of, here two, shim stacks, first and second shim stacks 218, 220. The clamp body 216, as shown in detail in FIG. 10, is generally configured as a U shaped channel having a base 222 and opposed first and second sides 224, 226 extending from opposed sides of the base 222 in the shorter direction thereof. The base 222 includes, extending between the first and second sides 224, 226 thereof, a slot facing base wall surface 232, and each of the side walls include a slot facing wall surface, here a first slot facing wall surface 228 and a second slot facing wall surface 230. The first and second sides 224, 226 of the clamp body 216 extend away from the base 222 to terminate in first and second wrist facing surfaces 234, 236, which are planar surfaces co-planar with one another. The outer side walls the sides 224, 226 are configured as first and second side wall surfaces 238, 240, each extending from the end of one of the first and second wrist facing surfaces 234, 236 to the base surface 242 of the base 222. The base surface 242 is generally planar and parallel to the first and second wrist facing walls 234, 236 and the slot facing base wall surface 232. the first and second slot facing wall surfaces 228, 230 define three boundary walls of a rod receiving slot 244 extending from a front wall surface 246 to a rear wall surface 248 of the clamp body 216. The front wall surface 246 and rear wall surface 248 extend across opposite ends of the base wall 242, first and second side wall surfaces 238, 240, first and second wrist facing surfaces 234, 236, first and second slot facing wall surfaces 228, 230 and base wall surface 232. A plurality of through bores 250 extend through the first and second sides 224, 226, and open at and through the base surface 242 at one end thereof, and through one of the first and second wrist facing surfaces 234, 236 at a second end thereof. As will be described herein, threaded fasteners, such as bolts, extend through the through bores 250 to be received in corresponding threaded bores (See FIG. 10) in the upper wall of the recess 210 of the wrist 108.

Referring to FIGS. 2, 7, 9 and 10, the wrist 108 includes a first flat face 254 on one side of the body 252 thereof, a second flat face 256 on the side of the body opposed to the first flat face 254, a third flat face 258 into which the proximal ends 202 of the rods 110 extend, and a fourth flat 260 face on the opposed side of the body 252 from the third flat face 258 and opposed end faces 262, 264. The rod receiving recess 210 extends inwardly of the first flat face 254 and the third flat face 258. Rod receiving recess 210 is bounded by opposed first and second recess facing surfaces 266, 268 extending inwardly of the wrist body, and generally perpendicularly from, the first flat face 254 and third flat face 258. A pair of opposed generally planar clamp limit wall faces 270, 272 extend inwardly from, and perpendicular to, the third flat face 258 of the wrist body 252, and perpendicularly from the inner terminus of the first and second recess facing surface 266, 268 and are co-planar with one another. A pair of shim stack side walls 274, 276 extend generally perpendicularly from the ends of the clamp limit wall faces 270, 272 distal to the first and second recess facing surfaces 266, 268, respectively, and terminate at a shim stack limit surface 278 extends therebetween. The shim stack side walls 274, 276 and shim stack limit surface 278 which together define three sides of a shim stack recess 280 which opens into the rod receiving recess 210. The shim stack recess 280 ends inwardly at an inward shim stack limit wall surface 282 extending from the inward of the clamp body 216 ends of the shim stack sidewalls 274, 276 and the shim stack limit surface 278. Similarly the rod receiving recess 210 ends inwardly of the third face 258 at a rod receiving recess limit wall 284 extending from the inner of the clamp body 216 ends of the first and second recess facing surfaces 266, 268, and the opposed generally planar clamp limit wall faces 270, 272, and formed as a continuation of the shim stack limit wall 282. A plurality of threaded clamp fastener openings 281 extend inwardly of each of the clamp limit wall faces 270, 272, corresponding to the through bores 250 extending through the first and second sides 224, 226 of the clamp body 216.

Each shim stack 218, 220 includes a central stiffener 286 and a first, and a second, compliant shim member 288, 290 on opposed upper and lower side wall surfaces 292, 294 of the central stiffener 286. Here, the stiffener 286 can have a continuous thickness across its length, or, can be wedge-shaped such that the thickness thereof in the shim stack 220 contacting the slot facing base wall 232 of the clamp body 216 is greater nearer the third face 258 of the wrist body 216 and thinner closer to the rod receiving limit wall surface 284. The stiffener in the first shim stack 218 is thinner greater nearer the third face 258 of the wrist body 216 and thinner closer to the inward shim stack limit wall surface 282. This construct can be used to impose an upward tilt on the rod 110 received therein to compensate for droop over the length of the rod 110 from its proximal end 202 to distal end 205. Each compliant shim member 288, 290 includes a stiffener facing side surface 296 and a free facing side surface 300 and a surrounding wall surface 302.

To secure the proximal end 202 of the rod 110 in the recess 210 of the wrist 108, the first shim stack 218 is located in the shim stack recess 280 such that the free facing side surface 300 of one of the compliant members faces and contacts the shim stack limit surface 278, while the other free facing side surface 300 on the opposite side of the shim stack 218 faces the rod receiving recess 244. Then the rod 110, with the coating 30 thereon facing the free facing side surface 300 of the shim stack 218 facing the rod receiving recess 244 is placed into the rod receiving recess 244, with the proximal end wall surface 298 (FIG. 16) of the rod 110 facing the rod receiving recess limit wall surface 284, in close proximity or in contact therewith. Then, the second shim stack 220 is located over the lower fourth wall 44 of proximal end of the rod 110, and the clamp assembly 216 fitted thereover such that the side walls 224, 226 of the clamp extend between the surfaces 42, 43 of the rod 110 and the first and second recess facing surfaces 266, 268, respectively, and the rod receiving recess 210, and the slot facing base wall 232 clamp body 216 contacts the otherwise exposed free facing side surface 300 of the second shim stack. The threaded shanks of threaded fasteners (not shown) are extended inwardly of the through bores 250 in the clamp body 216 and threaded into the threaded openings 281 in the clamp limit wall faces 264, 276, such that the enlarged heads thereof will bear against the base wall 242 of the clamp body. By tightening the fasteners in the threaded openings 281, the clamp body 216 is pulled into the rod receiving recess 210 in the wrist 108 to squeeze the conformable portions of the shim stacks 218, 220 and secure the rod in the wrist 208.

Here, the conformable material of the compliant shim members 288, 290 of the shim stacks 218, 220, or at least the compliant shim members 288, 290 of the shim stack 218 contacting the conductive coating 30, is configured from a conductive elastomer. Thus, an electrical path is formed between the conductive coating 30 on the rod 110, through the adjacent compliant member, through the electrically stiffener 286, through the other compliant member in contact with the wrist 106, and thus into the wrist 208.

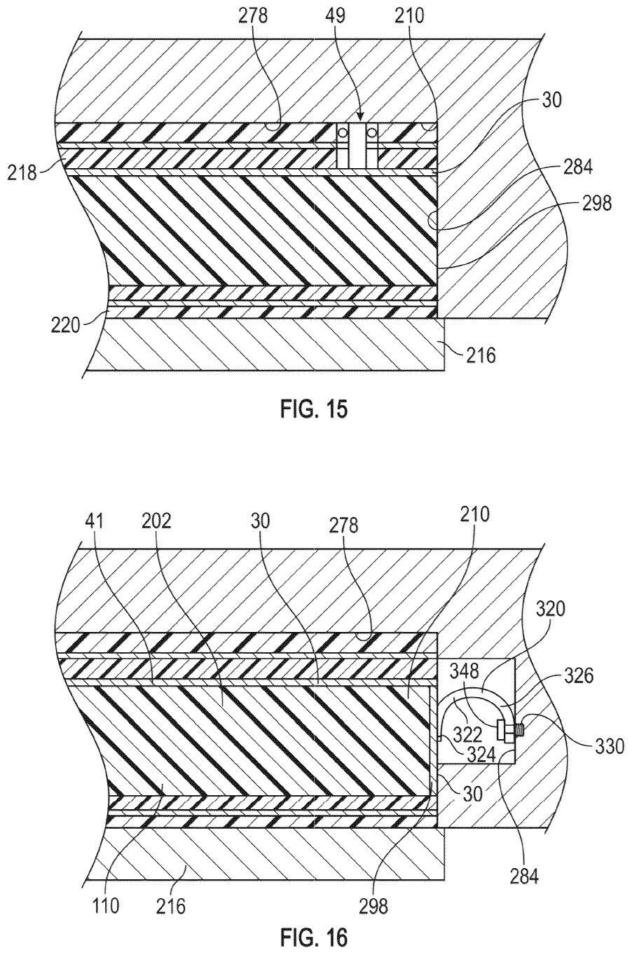

Referring now to FIG. 15, an alternative embodiment of the connection of the proximal end 202 or the rod 110 to the wrist 208 is shown, in which a conductive spring or a spring loaded pin 49 is provided in the first shim stack and extends therethrough. The conductive spring or spring loaded pin 49 is made of a conductive material of a sufficient electrical conductivity to form an electrically conductive path between its contact location with the conductive coating 30 and with the shim stack limit surface 278 of the wrist 108 to dissipate charge from the rod 110 to the wrist 108.

Referring now to FIG. 16, an additional alternative embodiment of the connection of the proximal end 202 of the rod 110 to the wrist 108 is shown, in which a conductive clip 320 is provided within the recess in the wrist 108. The clip 320 is, for example, configured of spring steel having a half loop portion 322, a contact 324 and a retainer portion 326. Contact 324 and retainer portion 326 are generally straight flat continuing portions of the loop portion 322 extending from opposed ends thereof. Retainer portion 326 is affixed to the rod receiving limit wall surface 284, for example by a threaded fastener 328 threaded into a threaded clip mounting bore 330 extending inwardly of the rod receiving limit wall surface 284 to ensure electrical continuity between the clip 320 and the body of the wrist 108. Half loop portion 322 supports the contact 324 inwardly of the rod receiving recess 210. Here, the rear first surface 41 of the rod continuously and thereover. Thus, the contact 324 can make contact with the conductive coating, to ensure electrical continuity between the conductive coating 30 and the wrist 108.

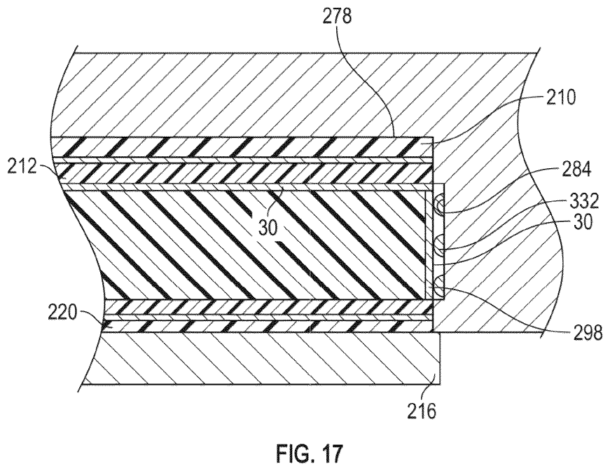

Referring now to FIG. 17, an additional alternative embodiment is shown in which a plurality of conductive protrusions 332 are provided extending outwardly from the rod receiving recess limit wall 284. These protrusions can be configured, for example, from a conductive elastomeric material connected to the rod receiving recess limit wall 284 by, for example, a conductive adhesive. Alternatively, the protrusions may be connected to a conductive base plate, and the base plate secured to the rod receiving recess limit wall 284 by a threaded fastener of other fastening paradigm. In this embodiment, the back surface 298 of the rod 110 is coated with a continuation of the conductive coating 30 of the surface of the rod 110 to face and contact the plurality of protrusions 332. The coating on the coated rod 110 will thus contact and create an electrical connection to the plurality of protrusions 332 as the rod 110 is inserted into the recess 210 of the wrist 108, forming an electrical path from the coating 30 to the wrist 108 and thereby allowing charge to dissipate from the rod 110 to the wrist 108.

As previously discussed herein with respect to FIG. 2, the end effector assembly 120 may include both a rod 110 extending from the wrist 108, and an extension rod 116 extending from the distal end 205 of each rod 110. Here, the extension rods 116 are likewise rectangular in cross section, and include the conductive coating 30 on the first surface 41a thereof, and a conductive pad 60 structure on conductive coating 30 on the first surface 41a thereof. Here, electrical continuity between the conductive coating 30 on the extension rod 116, and the conductive coating 30 on the rod 110 it is connected to, must be ensured.

FIG. 18 depicts one embodiment of a method for fastening the distal end 205 of the rod 110 to the extension rod 116 of the end effector assembly 120. A rabbet 316 is formed in the rod 110 at the distal end 205 thereof, to form a ledge 340 and a sidewall 342, such that the extension rod 116 is receivable and received and supported on the ledge 340 and alongside the sidewall 342. An electrically conductive side pad 344 is located between the extension rod 116 and the sidewall 342 to minimize abrasion between the facing surfaces of the rod 110 and the extension rod 116 due to differences in thermal expansion, vibration, handling during assembly and disassembly, and the like. Optionally, an additional pad (not shown) may be disposed between the third surface 43a of the extension rod 116 and the ledge 340 to further minimize abrasion between the rod 110 and the extension rod 116. The pad 344 (and the optional pad not shown) may be made of rubber, aluminum film, or other suitable material. The pad 344 additionally reduces vibrations transferred to the extension rod 116 from the rod 110 and vice versa. An edge relief, such as a chamfer 354, may be provided to minimize damage during assembly. Other forms of edge relief other than the chamfer 354 may also be utilized, such as a radius or other shape. The extension rod 116 is secured to the rod 110 by a plurality of fasteners. In the embodiment depicted in FIG. 20, five threaded fasteners 346 pass through a plurality of holes provided in the extension rod 116 and the rod 110 through the sidewall 342 of the rabbet 316 and are held secure by five nuts 348. A pair of plates 352 is provided on the second side 42a of the extension rod 116 and third side 43 of the rod 110 to evenly distribute the load applied by the fasteners across the surface of the rod 110 and the extension rod 117. Plates 352 may be made of stainless steel, titanium alloy, or other suitable material.

Here, to ensure electrical continuity between the conductive coating 30 on the extension rod 116 and on the rod 110, the conductive coating 30 on the extension rod 116 extends from the first surface 41a over the edge thereof to the third surface 43a, and the conductive coating on the first surface 41 of the rod extends therefrom and over the side surface 342 of the rabbet 316. Thus, an electrically conductive bridge is formed from a conductive pad 60 on the conductive coating 30 on the extension rod 116, through the conductive coating 30 on the third surface 43a thereof, through the electrically conductive side pad 344, and to the conductive coating 30 on the sidewall 342 of the rabbet 316. Thus, each conductive pad 60 on the extension rod 116 has a conductive path to the wrist 108.

While the foregoing is directed to embodiments of the present disclosure, other and further embodiments of the disclosure may be devised without departing from the basic scope thereof, and the scope thereof is determined by the claims that follow.

What is claimed is:

1. An end effector for a substrate supporting and transferring system, comprising:
a wrist
a plurality of electrically insulative substrate support members extending from the wrist and having a proximal portion supported therein, the substrate supporting member including a substrate facing surface, a conductive coating, and at least a first conductive member disposed upon and in electrical contact with the conductive coating, the conductive coating extending from the conductive member to the proximal end of the support member; and
a connection member extending between the conductive coating and the wrist.

2. The end effector of claim 1, further comprising a second conductive member disposed upon and in electrical contact with the conductive coating, the second conductive member interposed on the support member at a location intermediate of the first conductive member and the wrist.

3. The end effector of claim 1, wherein the substrate support member comprises a rod having a planar substrate-facing surface.

4. The end effector of claim 3, wherein the rod is rectangular in cross section.

5. The end effector of claim 1, wherein the connection member includes at least one conductive shim extending between and in electrical contact with the conductive coating and a surface of the wrist.

6. The end effector of claim 1, wherein the connection member includes a compliant electrically conductive member contacting the conductive coating and the wrist.

7. The end effector of claim 6, wherein the compliant electrically conductive member comprises a spring loaded contact.

8. The end effector of claim 6, wherein the compliant electrically conductive member comprises a conductive clip.

9. The end effector of claim 6, wherein the compliant electrically conductive member comprises at least one conductive protrusion extending from a surface of the wrist.

10. The end effector of claim 6, further comprising a recess in the wrist, wherein the recess is sized to receive a clamp member and a shim.

11. A method of supporting a substrate to reduce the occurrence of electrostatic discharge within the substrate or one or more layers of material formed thereon, comprising:
providing an insulative substrate support member extending from a base plate, the substrate support member having a substrate facing surface and at least one protrusion extending therefrom and including a support surface configured to contact a substrate; and
providing a conductive path from the support surface to the base plate.

12. The method of claim 11, wherein the base plate is an end effector wrist connected to a robot, and the substrate support member is provided as an insulative rod having a conductive coating thereon.

13. The method of claim 12, further comprising providing the protrusion as a compliant conductive pad in electrical contact with the conductive coating.

14. The method of claim 11, wherein the base plate is electrically connected to an electrical ground.

15. The method of claim 11, further comprising providing the support member as having a distal end and a proximal end; and
connecting the proximal end to the base plate to achieve electrical continuity between the support member and the base plate.

16. An end effector for a substrate supporting and transferring system, comprising:
a wrist
a plurality of substrate support members extending from the wrist and having a proximal portion supported therein, the substrate supporting member including a substrate facing surface, a conductive coating, and at least a first conductive member disposed upon and in electrical contact with the conductive coating, the conductive coating extending from the conductive member to the proximal end of the support member; and
an electrically conductive connection member extending between the conductive coating and the wrist.

17. The end effector of claim 16, further comprising a second conductive member disposed upon and in electrical contact with the conductive coating, the second conductive member interposed on the support member at a location intermediate of the first conductive member and the wrist.

18. The end effector of claim 16, wherein the connection member includes at least one conductive shim extending between and in electrical contact with the conductive coating and a surface of the wrist.

19. The end effector of claim 16, wherein the connection member includes a compliant electrically conductive member contacting the conductive coating and the wrist.

20. The end effector of claim 19, further comprising a recess in the wrist, wherein the recess is sized to receive a clamp member and a shim.
